(19) United States
(12) Patent Application Publication
(10) Pub. No.: US 2009/0236627 A1
(43) Pub. Date: Sep. 24, 2009

(54) METHOD OF FORMING METAL WIRING

(76) Inventors: Jang-Sub Kim, Suwon-si (KR); Yoon-Ho Kang, Yongin-si (KR); Yang-Ho Bae, Seoul (KR); Pil-Sang Yun, Seoul (KR); Chang-oh Jeong, Suwon-si (KR); Soon-Kwon Lim, Yongin-si (KR); Hong-Sick Park, Suwon-si (KR); Ning Hong Long, Suwon-si (KR); Do-Hyun Kim, Seoul (KR); Seung-Jae Jung, Seoul (KR)

Correspondence Address: Haynes and Boone, LLP;IP Section, 2323 Victory Avenue, SUITE 700, Dallas, TX, 75219, US

(21) Appl. No.: 12/357,207

(22) Filed: Jan. 21, 2009

(30) Foreign Application Priority Data
Mar. 19, 2008 (KR) 10-2008-0025537
Apr. 7, 2008 (KR) 10-2008-0032382

(51) Int. Cl. H01L 33/00; G03F 7/26; H01L 21/02; C25D 7/06; H01L 23/52

(52) U.S. Cl. 257/99; 430/314; 438/652; 205/122; 257/773; 257/E23.141; 257/E21.002; 257/E33.066

(57) ABSTRACT

Provided is a method of forming metal wiring. The method includes forming a photosensitive film pattern on a substrate, hydrophobicizing at least part of the photosensitive film pattern, coating metal ink on the substrate having the photosensitive film pattern, forming a seed layer, and forming a metal layer. Alternatively, a trench is formed by using the photosensitive film pattern as a mask, and metal aerosol is sprayed to form the seed layer and then the metal layer. In this method, there is no need to form a metal thin film on the photosensitive film pattern when the seed layer is formed. As a result, less metal is wasted, which, in turn, significantly reduces manufacturing costs.

This application claims priority from Korean Patent Application No. 10-2008-0025537 filed on Mar. 19, 2008 and 10-2008-0032382 filed on Apr. 7, 2008 in the Korean Intellectual Property Office, the disclosure of which is incorporated herein by reference in its entirety.

### BACKGROUND OF THE INVENTION

1. Field of the Invention

The present invention relates to a method of forming metal wiring, and more particularly, to a method of forming buried metal wiring.

2. Description of the Related Art

Liquid crystal displays (LCDs) are one of the most widely used flat panel displays (FPDs). An LCD includes a lower substrate on which gate lines, data lines, pixel electrodes, TFTs and the like are formed, an upper substrate on which common electrodes are formed, and a liquid crystal layer which is interposed between the lower and upper substrates. The LCD applies voltages to the pixel electrodes and the common electrodes and thus generates an electric field in the liquid crystal layer. By using the generated electric field, the LCD determines the alignment of liquid crystal molecules of the liquid crystal layer, thereby controlling the polarization of light that passes through. As a result, a desired image is displayed on the LCD.

In order to realize a large and high-definition LCD, it is desirable to reduce resistance of metal wiring. Thus, a material having low resistivity, such as copper (Cu) and silver (Ag), may be used to form metal wiring. However, even when metal wiring is made of a material having low resistivity, it is usually desirable to increase the width or thickness of the metal wiring in order to further reduce the resistance of the metal wiring.

If the width of the metal wiring is increased, the width of a pixel region often is reduced by the same width that the metal is increased by. Consequently, an aperture ratio is reduced. If the thickness of the metal wiring is increased, for example, if a gate line having gate electrodes is formed to a thickness of 4,000 to 5,000 Å or greater, there is a large step height between a substrate and the gate line. In addition, the step height is further increased by source and drain electrodes which overlap the gate electrodes. If such a large step height is created in a lower substrate, it undermines liquid crystal filling. Accordingly, liquid crystal molecules are not uniformly aligned, and a uniform transmittance cannot be obtained, thereby deteriorating display quality of the LCD.

For this reason, a method of forming buried metal wiring has been suggested. In this method, a trench is formed in a substrate, and metal wiring is formed in the trench. Specifically, to form buried metal wiring, a photosensitive film pattern is formed on a substrate, and a trench is formed by a wet etching process. Then, a seed layer is formed on a bottom surface of the trench by sputtering, and Cu is formed by a plating process.

Here, a metal thin film with a thickness similar to that of the seed layer is formed on the photosensitive film pattern when the seed layer is formed by sputtering, and removed when the photosensitive film pattern is lifted off. The discarded metal thin film is essentially wasted, which in turn increases manufacturing costs. In addition, if the trench is formed sufficiently deeply, the metal thin film formed on the photosensitive film pattern also becomes thicker. Therefore, it is difficult to remove the metal thin film in the lift-off process.

### SUMMARY OF THE INVENTION

Aspects of the present invention provide a method of forming buried metal wiring, in which a waste of metal material can be prevented, and thus manufacturing costs can be reduced.

Aspects of the present invention also provide a method of forming buried metal wiring, in which no metal thin film is formed on a photosensitive film pattern when a seed layer is formed, thereby preventing a waste of metal material.

However, aspects of the present invention are not restricted to the one set forth herein. The above and other aspects of the present invention will become more apparent to one of ordinary skill in the art to which the present invention pertains by referencing the detailed description of the present invention given below.

According to an aspect of the present invention, there is provided a method of forming metal wiring. The method includes: forming a photosensitive film pattern on a substrate; forming a trench by etching the substrate using the photosensitive film pattern as a mask; forming a seed layer by coating a fluid material, which contains metal, on the trench; and forming a metal layer on the seed layer.

According to another aspect of the present invention, there is provided a method of forming metal wiring. The method includes: forming an insulating film pattern on a substrate; forming a seed layer by coating a fluid material, which contains metal, on a space between portions of the insulating film pattern; and forming a metal layer on the seed layer.

According to another aspect of the present invention, there is provided a metal wiring comprising: a trench formed in a substrate; a seed layer formed in the trench and comprising micropores; and a metal layer formed on the seed layer in the trench.

According to another aspect of the present invention, there is provided a metal wiring comprising: an insulating film pattern formed on a substrate and comprising a predetermined space between portions thereof; a seed layer formed in the predetermined space and comprising micropores; and a metal layer formed on the seed layer in the predetermined space.

According to another aspect of the present invention, there is provided a liquid crystal display (LCD) comprising: a trench formed in a substrate; a first seed layer formed in the trench and comprising first micropores; a gate line formed on the first seed layer in the trench; and a gate insulating film formed on the substrate and the gate line.

### BRIEF DESCRIPTION OF THE DRAWINGS

The above and other aspects and features of the present invention will become more apparent by describing in detail exemplary embodiments thereof with reference to the attached drawings, in which:

FIGS. 1A through 1E are sequential cross-sectional views for explaining a method of forming metal wiring according to a first exemplary embodiment of the present invention;

FIGS. 2A through 2C are sequential cross-sectional views for explaining a method of forming metal wiring according to a second exemplary embodiment of the present invention;

FIGS. 3A through 3D are sequential cross-sectional views for explaining a method of forming metal wiring according to a third exemplary embodiment of the present invention;

FIG. 4 is a cross-sectional view of a thin-film transistor (TFT) using a method of forming metal wiring according to the present invention;

FIG. 5 is a plan view of a liquid crystal display (LCD) using a method of forming metal wiring according to the present invention;

FIG. 6 is a cross-sectional view of the LCD taken along a line I-I′ of FIG. 5;

FIG. 7 is a cross-sectional view of the LCD taken along a line II-II′ of FIG. 5; and

FIG. 8 is a cross-sectional view of the LCD taken along a line III-III′ of FIG. 5.

### DETAILED DESCRIPTION OF THE INVENTION

Advantages and features of the present invention and methods of accomplishing the same may be understood more readily by reference to the following detailed description of exemplary embodiments and the accompanying drawings. The present invention, including numerical values of various variables, may, however, be embodied in many different forms and take on many different values, and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the thickness of the layers and regions are exaggerated for clarity. Like reference numerals refer to like elements throughout the specification. When an element such as a layer, film, region, or substrate is referred to as being “on” another element, it can be directly on the other element or intervening elements may also be present.

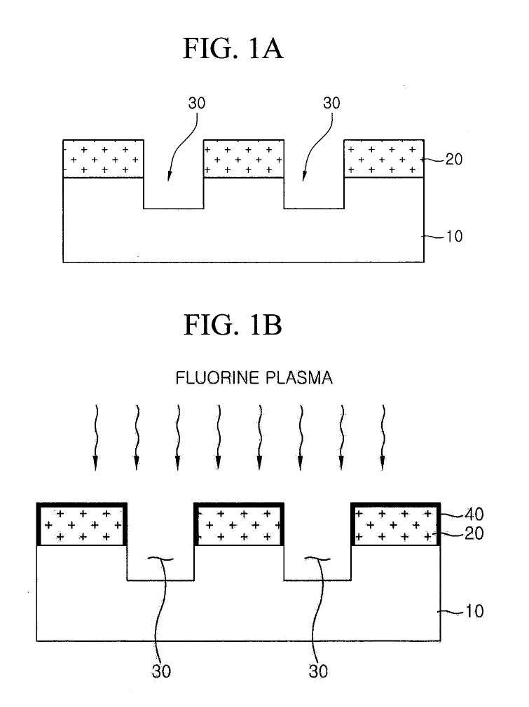

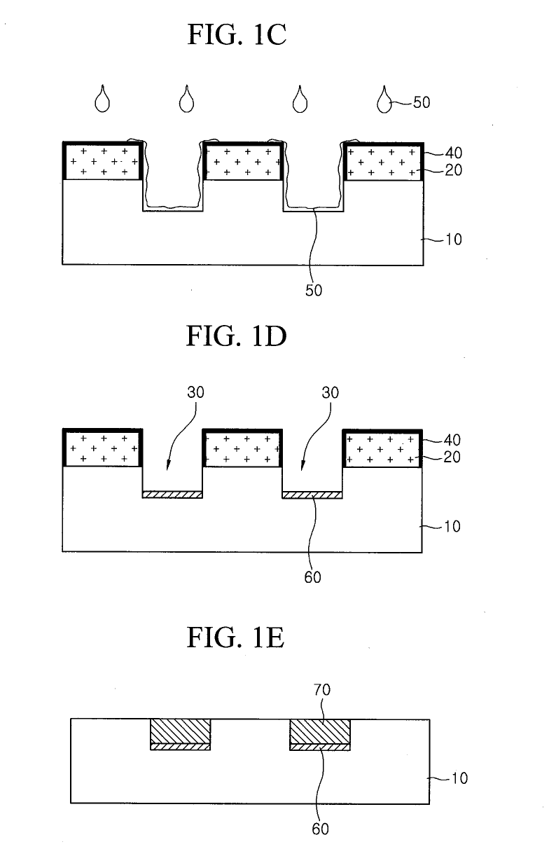

FIGS. 1A through 1E are sequential cross-sectional views for explaining a method of forming metal wiring according to a first exemplary embodiment of the present invention.

Referring to FIG. 1A, a photosensitive film is formed on a substrate 10. Then, the photosensitive film is exposed and developed by using a predetermined mask (not shown) to form a photosensitive film pattern 20 which exposes a predetermined region of the substrate 10. The substrate 10 is etched to a predetermined depth in an etching process by using the photosensitive film pattern 20 as a mask. As a result, a trench 30 is formed.

The substrate 10 may be a substrate having a light transmittance of 80% or more, for example, a transparent insulating substrate such as a glass substrate or a plastic (PE, PES, PET, PEN, etc.) substrate. The depth of the trench 30 may vary according to a thickness of a metal layer that is to be formed. For example, the depth of the trench 30 may be approximately 100 to 25,000 Å. The trench 30 may be formed in a wet etching process by using an NH4HF2 or HF solution. In addition, sodium ions (Na+) and potassium ions (K+) may be added to the etching solution. Here, the acidity (ph) of the etching solution may be 4 to 5, and an etch rate of the wet etching process may be 0.2 to 0.6 μm/min. If the etch rate of the wet etching process is smaller than the above range, the time required for the wet etching process is increased. On the other hand, if the etch rate of the wet etching process exceeds the above range, it is difficult to control the wet etching process.

Referring to FIG. 1B, a surface of the photosensitive film pattern 20 is hydrophobicized. To this end, fluorine-containing plasma is irradiated to the photosensitive film pattern 20 to form a hydrophobic film 40 on the surface of the photosensitive film pattern 20, and preferably, an exposed surface of the photosensitive film pattern 20. For example, the substrate 10 having the photosensitive film pattern 20 formed thereon is loaded into a plasma chamber. Then, 5 to 10 sccm of fluorine-containing gas and 5 to 10 sccm of oxygen gas are introduced into the plasma chamber from room temperature to 75° C. and under a pressure of 10 to 50 mTorr. In addition, a high-frequency power of 1,000 to 2,000 W and a high-frequency power of 100 to 500 W are applied to an upper electrode and a lower electrode, respectively, thereby generating plasma. The surface of the photosensitive film pattern 20 is treated with the generated plasma to form the hydrophobic film 40.

The surface of the photosensitive film pattern 20 may also be plasma-treated by a scanning method. For example, the substrate 10 having the photosensitive film pattern 20 can be moved at several meters per minute and passed through the chamber with the generated plasma. In so doing, the surface of the photosensitive film pattern 20 is plasma-treated. The hydrophobic film 40 is formed very thin, i.e., formed to a thickness of several Å. In addition, SF6, CF4, C2F6, C4F8 or various other fluorine-containing gases may be used as the fluorine-containing gas.

Referring to FIG. 1C, metal ink 50 is coated on the photosensitive film pattern 20, which has the hydrophobic film 40 formed thereon, by using, for example, an inkjet method. Since the hydrophobic film 40 is formed on the surface of the photosensitive film pattern 20, if the metal ink 50 is dropped onto the photosensitive film pattern 20 having the hydrophobic film 40 by using the inkjet method, the metal ink 50 is not coated on the photosensitive film pattern 20 but only on a bottom surface of the trench 30. Here, the inkjet method may be a thermal method or a piezo method. In one embodiment, the metal ink 50 is fabricated by combining metal nanoparticles of approximately 3 to 6 nm in size with an organic solvent and a surfactant. The metal ink 50 has a viscosity of approximately 1 to 20 cP and a surface tension of approximately 20 to 50 mN/m, and an organic solvent having a low steam pressure is used to prevent nozzle clogging of an inkjet head.

The metal ink 50 is dropped through a plurality of inkjet heads having a maximum injection velocity of, for example, 32 kHz. A metal material used for the metal ink 50 may be molybdenum (Mo), copper (Cu), aluminum (Al), titanium (Ti), silver (Ag), tantalum (Ta), titanium nitride (TiN), or an alloy of the same. Alternatively, the metal ink 50 may be made of an organic compound having electric conductivity, such as polyacetylene, or an organic metal containing an organic metal compound which contains a combination of metal and carbon.

Referring to FIG. 1D, the substrate 10 coated with the metal ink 50 is heat-treated for 20 to 30 minutes at 200 to 300° C. to remove solvent from the metal ink 50 and thus form a seed layer 60 on the bottom surface of the trench 30. Here, the seed layer 60 is formed to a thickness of approximately 300 to 700 Å. Since heat treatment may cause metal expansion or combustion of an organic material, micropores may be formed in the seed layer 60.

Referring to FIG. 1E, a lift-off process is performed to remove the photosensitive film pattern 20 from the substrate 10. In addition, a plating process is performed to form a metal layer 70 which fills the trench 30. The plating process may be an electric or electroless plating process. The metal layer 70 may be made of various metals or alloys as well as Cu. In the plating process, the metal layer 70 is grown from the seed layer 60 to a surface level of the substrate 10. Here, a surface level of the metal layer 70 may be equal to or lower than that of the substrate 10. For example, the surface level of the metal layer 70 may be lower than that of the substrate 10 by approximately 500 Å.

The above-described process illustrates one exemplary method of forming metal wiring within the trench 30 of the substrate 10. In addition, if micropores are formed in the seed layer 60 after heat treatment, the metal wiring may be composed of the metal layer 70 and the seed layer 60 having the micropores. In this case, the metal layer 70 may not have micropores.

In the present embodiment, the surface of the photosensitive film pattern 20 is processed using fluorine-containing plasma to form the hydrophobic film 40. However, the present invention is not limited thereto. That is, the photosensitive film pattern 20 may be made of a material having hydrophobic characteristics, such as a CH3 group. For example, octadecyl trichloro silane (OTS) may be added to photosensitive film pattern 20 so that the photosensitive film pattern 20 can have hydrophobic characteristics. When the photosensitive film pattern 20 is made of a hydrophilic material, the surface of the photosensitive film pattern 20 may be processed using a fluorine-containing material and OTS, so that the photosensitive film pattern 20 can have hydrophobicity.

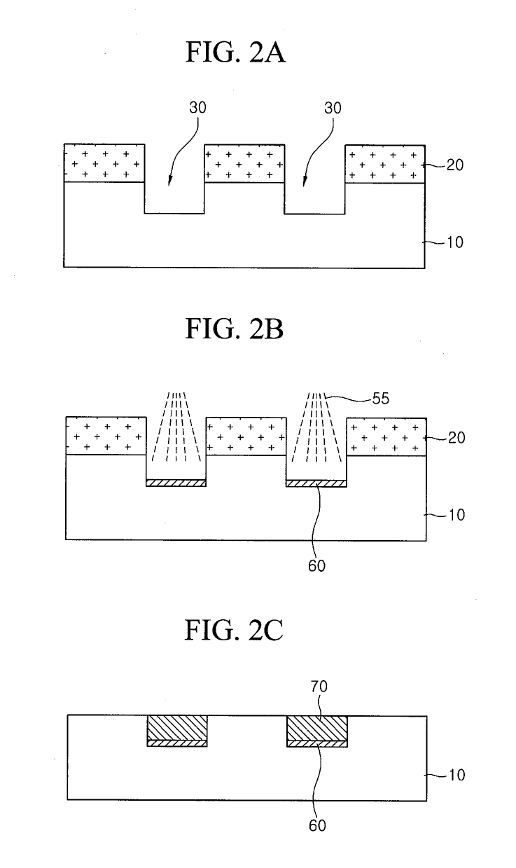

FIGS. 2A through 2C are sequential cross-sectional views for explaining a method of forming metal wiring according to a second exemplary embodiment of the present invention. In this method, a photosensitive film pattern is not hydrophobicized, and a seed layer is not formed on the photosensitive film pattern. No overlapping descriptions of the first and second exemplary embodiments of the present invention will be given below.

Referring to FIG. 2A, a photosensitive film is formed on a substrate 10. Then, the photosensitive film is exposed and developed by using a predetermined mask (not shown) to form a photosensitive film pattern 20 which exposes a predetermined region of the substrate 10. The substrate 10 is etched to a predetermined depth in an etching process by using the photosensitive film pattern 20 as a mask. As a result, a trench 30 is formed.

Referring to FIG. 2B, a maskless mesoscale material deposition (M3D) process, in which aerosol 55 containing a metal material is sprayed, is performed to form a seed layer 60 on the substrate 10 within the trench 30. The aerosol 55 can be fabricated by aerosolizing a metal material using an ultrasonic converter or a pneumatic sprayer. The metal material may be any one of a metal precursor, a metal colloidal, a metal paste, and a metal corpuscle, each containing Mo, Cu, Al, Ti, Ag, Ta, TiN or an alloy of the same. The aerosol 55 may be an organic compound having electrical conductivity, such as polyacetylene, or an organic metal containing an organic metal compound which contains a combination of metal and carbon.

The aerosol 55 can be sprayed through an injection pipe with a diameter of approximately 100 to 500 μm. The aerosol 55 is concentrated in ⅕to 1/10of the diameter of the injection pipe and is sprayed accordingly. The injection pipe and the trench 30 are separated from each other by approximately 3 to 5 mm. The aerosol 55 is sprayed while the injection pipe or the substrate 10 is moved. Then, the substrate 10 is heat-treated at, e.g., 200 to 300° C. to form the seed layer 60. In this case, heat treatment may cause metal expansion or combustion of an organic material. Accordingly, micropores may be formed in the seed layer 60. Thus, the seed layer 60 may be formed at a desired position, that is, on the substrate 10 within the trench 30. The seed layer 60 is formed to a thickness of approximately 300 to 700 Å.

Referring to FIG. 2C, a lift-off process is performed to remove the photosensitive film pattern 20 from the substrate 10. In addition, a plating process is performed to form a metal layer. 70 which fills the trench 30. Here, a surface level of the metal layer 70 may be lower than that of the substrate 10. For example, the surface level of the metal layer 70 may be lower than that of the substrate 10 by approximately 500 Å.

As described above, in the present embodiment, metal wiring is formed within the trench 30 of the substrate 10. In addition, if micropores are formed in the seed layer 60 after heat treatment, the metal wiring may be composed of the metal layer 70 and the seed layer 60 having the micropores. In this case, the metal layer 70 may not have micropores.

In the present embodiment, an M3D process is performed on the substrate 10 having the photosensitive film pattern 20 to form the seed layer 60 on a bottom surface of the trench 30. However, the present invention is not limited thereto. That is, the M3D process may also be performed after the photosensitive film pattern 20 is removed from the substrate 10. In this case, the gap between the trench 30 and the injection pipe can be reduced, and thus the M3D process can be performed more precisely.

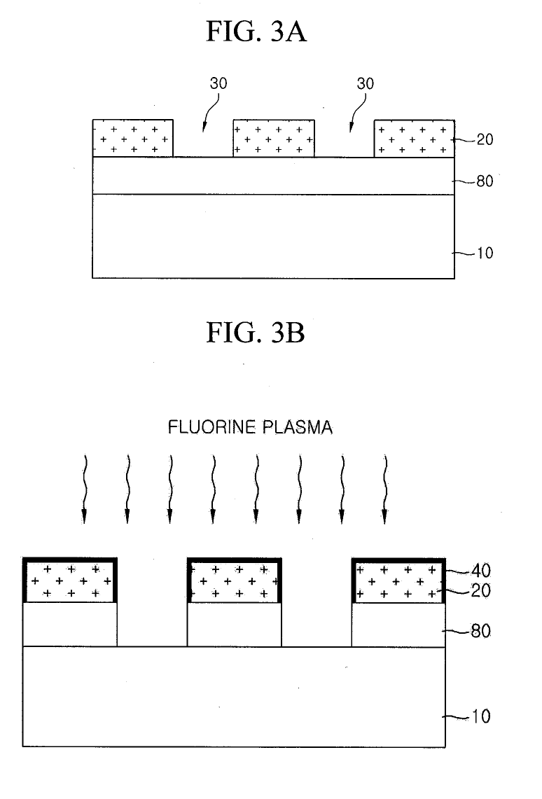

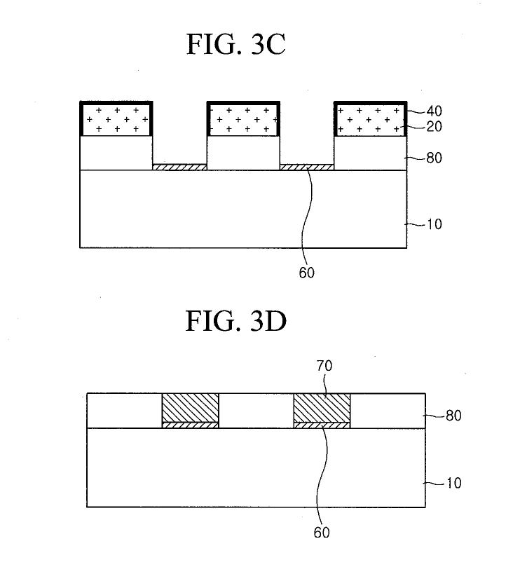

FIGS. 3A through 3D are sequential cross-sectional views for explaining a method of forming metal wiring according to a third exemplary embodiment of the present invention. No overlapping descriptions of the first through third exemplary embodiments of the present invention will be given below.

Referring to FIG. 3A, an insulating film 80 is formed on a substrate 10, and a photosensitive film pattern 20, which exposes a predetermined region of the insulating film 80, is formed on the insulating film 80. The insulating film 80 may be an organic insulating film or an inorganic insulating film. The organic insulating film may be made of at least one of cellulose derivatives, olefin-based resin, acrylic resin, vinylchloride resin, styrene resin, polyester resin, polyamide resin, polycarbonate resin, polycycloolefin resin, and epoxy resin. The inorganic insulating film may be a silicon dioxide (SiO2) film or a nitride silicon (SiNx) film. A thickness of the insulating film 80 may vary according to a thickness of a metal layer that is to be formed. For example, the thickness of the insulating film 80 may be approximately 100 to 25,000 Å.

The insulating film 80 can be etched in an etching process by using the photosensitive film pattern 20 as an etching mask to form a trench 30 which exposes a predetermined region of the substrate 10. The insulating film 80 may be etched by a dry etching process or a wet etching process.

Referring to FIG. 3B, fluorine-containing plasma is irradiated to the photosensitive film pattern 20 to form a hydrophobic film 40 on a surface of the photosensitive film pattern 20. In addition, SF6, CF4, C2F6, C4F8 or other various fluorine-containing gases may be used as the fluorine-containing gas.

The photosensitive film pattern 20 may be made of a material having hydrophobic characteristics, such as a CH3 group. For example, OTS may be added to the photosensitive film pattern 20, so that the photosensitive film pattern 20 can have hydrophobic characteristics. When the photosensitive film pattern 20 is made of a hydrophilic material, the surface of the photosensitive film pattern 20 may be processed using a fluorine-containing material and OTS, so that the photosensitive film pattern 20 possesses hydrophobicity.

Referring to FIG. 3C, metal ink is coated on the photosensitive film pattern 20, which has the hydrophobic film 40 thereon, by using an inkjet method. Then, the substrate 10 coated with the metal ink is heat-treated to form a seed layer 60. That is, since the hydrophobic film 40 is formed on the surface of the photosensitive film pattern 20, if the metal ink is dropped onto the photosensitive film pattern 20 having the hydrophobic film 40 by using the inkjet method, the metal ink is not coated on the photosensitive film pattern 20 but only on the substrate 10. Next, the substrate 10 is heat-treated to remove a solvent of the metal ink and thus form the seed layer 60.

Referring to FIG. 3D, a lift-off process is performed to remove the photosensitive film pattern 20 from the insulating film 80. In addition, a plating process is performed to grow a metal layer 70 from the seed layer 60 to a surface level of the insulating film 80.

In the present embodiment, the photosensitive film pattern 20 is hydrophobicized, and an inkjet process is performed according to the first exemplary embodiment in order to form the seed layer 60 and the metal layer 70 between portions of the insulating film 80 on the substrate 10. However, the present invention is not limited thereto. That is, after the insulating film 80 is formed on the substrate 10, an M3D process, in which aerosol made of a metal material is sprayed, may be performed according to the second exemplary embodiment in order to form the seed layer 60.

In addition, the seed layer 60 may be formed before the insulating film 80 if it is to be formed by moving the substrate 10 or the injection pipe. Then, the insulating film 80 may be patterned to expose the seed layer 60. If a photosensitive film having thermal resistance at 300° C. or above is used, no additional insulating film need be formed. Instead, the photosensitive film may be formed on the substrate 10 and patterned. Then, the seed layer 60 and the metal layer 70 may be formed between portions of the patterned photosensitive film.

In the above embodiments, after the seed layer 60 is formed, the metal layer 70 is formed in a plating process. However, the present invention is not limited thereto. For instance, after the seed layer 60 is formed, the metal layer 70 may instead be formed by an inkjet process or an M3D process. The process of forming the metal layer 70 may be performed before or after a lift-off process. When the metal layer 70 is formed by the inkjet process or the M3D process, a metal material used as metal ink or metal aerosol may be a metal material used for the seed layer 60, in particular, the metal layer 70 may be formed of a metal material containing Cu, Cr, cobalt (Co), nickel (Ni), indium tin oxide (ITO), indium zinc oxide (IZO), zinc aluminum oxide (ZAO) or an alloy of the same.

In the above embodiments, a case where metal wiring is formed on a substrate has been described. However, the present invention is not limited thereto. That is, metal wiring may also be formed on a predetermined structure on a substrate. In this case, the method according to the third exemplary embodiment may be applied to form buried metal wiring on the predetermined structure. For example, a thin-film transistor (TFT) may be manufactured by using the methods according to the first through third exemplary embodiments to form a gate electrode and using the method according to the third exemplary embodiment to form source and drain electrodes.

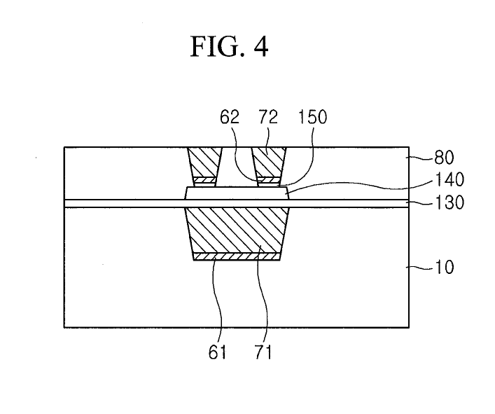

FIG. 4 shows a TFT which includes a gate electrode formed by using the method according to the first exemplary embodiment, and source and drain electrodes formed by using the method according to the third exemplary embodiment. Referring to FIG. 4, a trench is formed to a predetermined depth in a predetermined region of a substrate 10. Then, a first seed layer 61 is formed within the trench by an inkjet process or an M3D process. If the inkjet process is used, a surface of a photosensitive film pattern for forming the trench is hydrophobicized. Then, a first metal layer 71 is formed by a plating process, a successive inkjet process, or an M3D process. As a result, a buried gate electrode is formed.

A gate insulating film 130 is then formed on the substrate 10. After that, an active layer 140 is formed on the gate insulating film 130 to at least partially overlap the gate electrode. An ohmic contact layer 150, which is patterned into two separate regions, is formed on the active layer 140. Next, an insulating film 80 is formed on the entire surface of the resultant structure and then patterned to expose the ohmic contact layer 150.

The ohmic contact layer 150 is then patterned, and a second seed layer 62 is formed thereon, using an inkjet process or an M3D process. If the inkjet process is used, the surface of the photosensitive film pattern for etching the insulating film 80 is hydrophobicized. Then, a second metal layer 72 is formed by a plating process, a successive inkjet process, or an M3D process. As a result, buried source and drain electrodes are formed.

Metal wiring according to the above embodiments may be used in liquid crystal displays (LCDs). Specifically, the metal wiring may be used in a gate line having a gate electrode, a storage electrode line, and a data line having source and drain electrodes. In particular, the methods according to the first through third exemplary embodiments may be used to form a gate line having a gate electrode and a storage electrode line, and the method according to the third exemplary embodiment may be used to form a data line having source and drain electrodes. An LCD using metal wiring manufactured as described above will now be described.

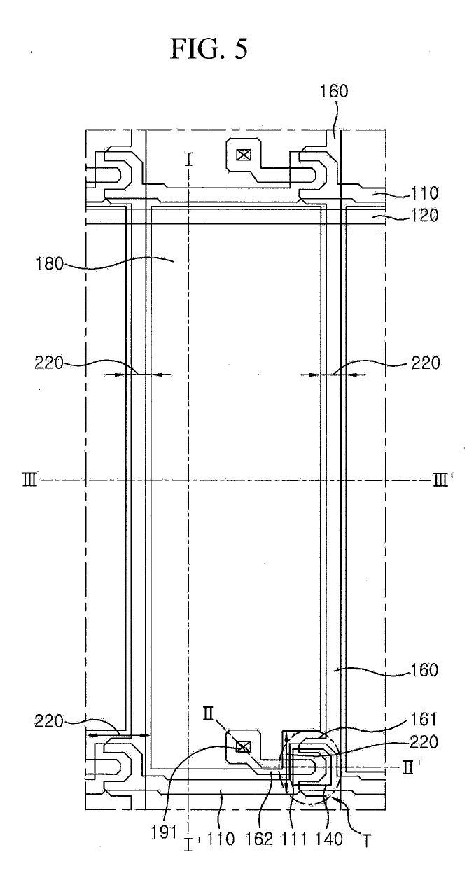

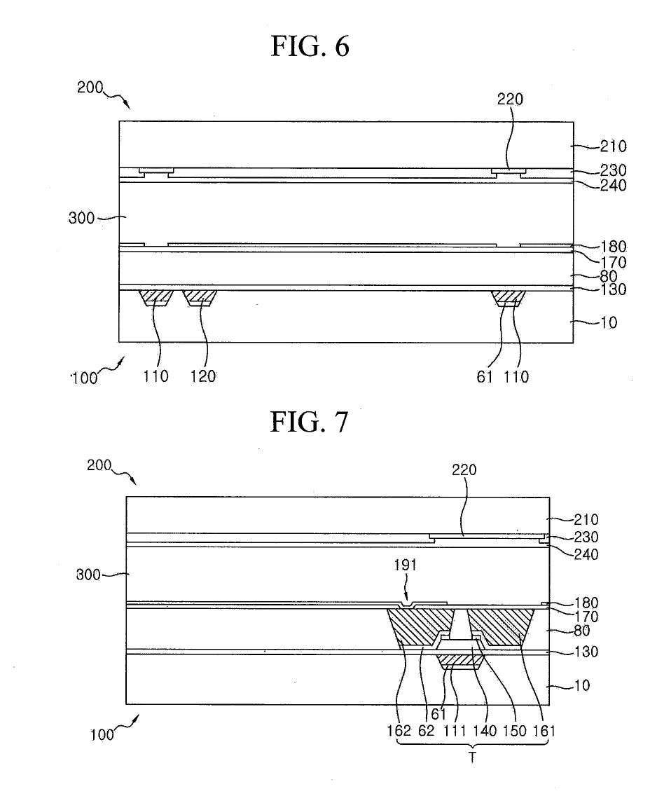

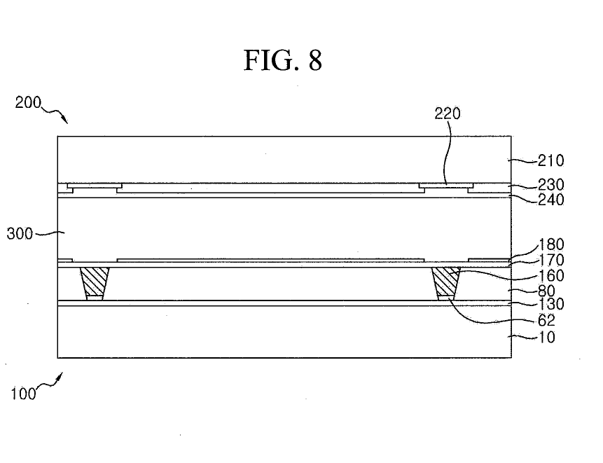

FIG. 5 is a plan view of an LCD using a method of forming metal wiring according to the present invention. FIGS. 6 through 8 are cross-sectional views of the LCD taken along lines I-I′, II-II′ and III-III′ of FIG. 5, respectively. In the LCD, a gate line having a gate electrode and a storage electrode line are formed by using the method according to the first exemplary embodiment, and a data line having source and drain electrodes is formed by using the method according to the third exemplary embodiment.

Referring to FIGS. 5 through 8, the LCD includes a lower substrate 100 which has a plurality of buried gate lines 110, a plurality of buried data lines 160, a passivation layer 170 and a pixel electrode 180, an upper substrate 200 which has a color filter 230 and a common electrode 240, and a liquid crystal layer 300 which is interposed between the lower substrate 100 and the upper substrate 200.

The lower substrate 100 includes the gate lines 110, the data lines 160, the passivation layer 170, the pixel electrode 180, and a TFT T. The gate lines 110 extend on a substrate 10 in a direction, are separated from each other by a predetermined gap, and are buried in the substrate 10. The data lines 160 are separated from each other by a predetermined gap, extend in the other direction to cross the gate lines 110, and are buried in an insulating film 80. The passivation layer 170 is formed on the data lines 160, and the pixel electrode 180 is formed on the passivation layer 170. The TFT T is connected to each of the gate lines 110, each of the data line 160, and the pixel electrode 180.

Specifically, the gate lines 110 extend in a direction, for example, a horizontal direction, and a portion of each of the gate lines 110 protrudes upward or downward to form a gate electrode 111. In addition, each of the gate lines 110 is formed to fill a trench which is formed in a predetermined region of the substrate 10. That is, a first seed layer 61 is formed on a bottom surface of the trench by an inkjet process or an M3D process, and a metal layer 70 is formed by a plating process, a successive inkjet process or an M3D process to form each of the gate lines 110.

A surface level of each of the gate lines 110 is lower than that of the substrate 10. For example, the gate lines 110 may be formed to a thickness of approximately 100 to 25,000 Å. In addition, the gate lines 110 may be bent in a predetermined manner. The first seed layer 61 may be made of an organic compound having electric conductivity or an organic metal. In addition, micropores may be formed in the first seed layer 61 after heat treatment. A storage electrode line 120 and the gate electrode 111, which will be described, may be formed on the first seed layer 61 having the micropores.

The storage electrode line 120 may be separated from each of the gate lines 110. A storage electrode line 120 is formed between pairs of the gate lines 110, and extends parallel to the gate lines 110. This storage electrode line 120 may be located an equal distance from the gate lines 110 or may be located adjacent to one of the gate lines 110. In addition, the storage electrode line 120 may be formed to have the same thickness and width as the gate lines 110 in the same process. Alternatively, the storage electrode line 120 may be formed to have a different width from that of the gate lines 110.

The gate lines 110 and the storage electrode line 120 may be made of at least one of Al, Cu, neodymium (Nd), Ag, Cr, Ti, Ta and Mo or may be made of an alloy of the same. Desirably, the gate lines 110 and the storage electrode line 120 may be made of Cu.

The gate insulating film 130 is formed on the substrate 10 having the gate lines 110 and the storage electrode line 120. The gate insulating film 130 may be a single layer or multiple layers formed by using an inorganic insulating film such as SiO2 or SiNx.

An active layer 140 made of a first semiconductor material is formed on the gate insulating film 130 which is disposed on the gate electrode 111, and an ohmic contact layer 150 made of a second semiconductor material is formed on the active layer 140. Here, the first semiconductor material includes amorphous silicon, and the second semiconductor material includes silicide or n+ hydrogenated amorphous silicon doped with n-type impurities in high concentration.

The insulating film 80 is formed on the entire surface of the substrate 10 having the gate insulating film 130, the active layer 140, and the ohmic contact layer 150. A predetermined region of the insulating film 80 is etched to partially expose the ohmic contact layer 150 and the gate insulating film 130. That is, the insulating film 80 includes an exposed space between portions thereof, that is, an exposed region in which each of the data lines 160 having source and drain electrodes 161 and 162 is to be formed. Then, a second seed layer 62 is formed on an exposed portion of the gate insulating film 130 and an exposed portion of the ohmic contact layer 150 in an inkjet process or an M3D process. That is, the second seed layer 62 extends in a direction, for example, a vertical direction, to cross each of the gate lines 110 and is separated from another seed layer. In addition, the second seed layer 60 partially overlaps the ohmic contact layer 150 formed on the gate electrode 111.

To form each of the data lines 160, a metal layer 70 is grown from the second seed layer 62, which is exposed by the insulating film 80 in a plating process, a successive inkjet process, or an M3D process. The data lines 160 extend in the vertical direction to cross the gate lines 110. In addition, the source electrode 161 is formed by protruding a portion of each of the data lines 160, and the drain electrode 162 is separated from the source electrode 161 by a predetermined gap. The data lines 160 having the source and drain electrodes 161 and 162 may be made of a material used for the gate lines 1110 and the storage electrode line 120. In addition, the data lines 160 may be bent in a predetermined manner. The second seed layer 62 may be made of an organic compound having electrical conductivity or an organic metal. In addition, micropores may be formed in the second seed layer 62 after heat treatment. The data lines 160 having the source and drain electrodes 161 and 162 may be formed on the second seed layer 62 having the micropores.

The TFT T allows a pixel signal, which is transmitted to each of the data lines 160 in response to a signal transmitted to each of the gate lines 110, to be charged in the pixel electrode 180. To this end, the TFT T includes a gate electrode 111 which is connected to each of the gate lines 110, a source electrode 161 which is connected to each of the data lines 160, a drain electrode 162 which is connected to the pixel electrode 180, and a gate insulating film 130. Also included are an active layer 140 and ohmic contact layer 150 which are sequentially formed between the gate electrode 111 and the source and drain electrodes 161 and 162. Here, the ohmic contact layer 150 may be formed on all regions of the active layer 140 excluding a channel region.

The passivation layer 170 is formed on the TFT T and each of the data lines 160. The passivation layer 170 may be made of a photosensitive organic material, a low-dielectric constant insulating material which is formed by plasma enhanced chemical vapor deposition (PECVD), or an inorganic material such as SiNx. A portion of the passivation layer 170 is removed to form a contact hole 191 which partially exposes the drain electrode 162.

The pixel electrode 180 is formed on the passivation layer 170 and connected to the drain electrode 162 by the contact hole 191. In addition, the pixel electrode 180 may include slit patterns (not shown) as domain partition portions used to control a direction in which liquid crystals are aligned. Alternatively, the pixel electrode 180 may include protrusion patterns as the domain partition portions used to control the direction in which the liquid crystals are aligned. The slit patterns (not shown) of the pixel electrode 180 and slit patterns (not shown) of the common electrode 240, which will be described later, may be used together to partition the liquid crystal layer 300 into a plurality of domains.

The upper substrate 200 includes a black matrix 220 selectively formed on a second insulating substrate 210, a color filter 230 formed between portions of the black matrix 220, and a common electrode 240 that can be formed on a whole surface of the upper substrate 200.

The black matrix 220 is formed between pixel regions. The black matrix 220 prevents leakage of light to regions other than pixel regions and optical interference between adjacent pixel regions. The black matrix 220 is typically made of a photosensitive organic material with a black pigment added. The black pigment may be carbon black or titanium oxide. Alternatively, the black matrix 220 may be made of a metal material such as Cr or CrOx.

Red (R), green (G) and blue (B) filters are repeated between the portions of the black matrix 220 to form the color filter 230. The color filter 230 adds color to light that has been irradiated by a light source and passed through the liquid crystal layer 300. The color filter 230 may be made of a photosensitive organic material.

The common electrode 240 is made of a transparent conductive material, such as ITO or IZO, and formed on the black matrix 220 and the color filter 230. The common electrode 240 and the pixel electrode 180 of the lower substrate 100 apply voltage to the liquid crystal layer 300. Slit patterns (not shown) may be formed in the common electrode 240. Together with the slit patterns (not shown) of the pixel electrode 180, the slit patterns (not shown) of the common electrode 240 may partition the liquid crystal layer 300 into a plurality of domains.

The above metal wiring can be used in various display devices other than LCDs and can also be used to form a buried gate of a semiconductor device. For example, if a steel or flexible substrate is used, the metal wiring can be used in organic light-emitting diodes (OLEDs) or flexible displays.

According to the present invention, at least part of a photosensitive film pattern, which is formed on a substrate, is hydrophobicized to form a trench, and metal ink is coated on the substrate to form a seed layer and then a metal layer. Alternatively, after the trench is formed by using the photosensitive film pattern as a mask, metal aerosol is sprayed over the substrate to form the seed layer and then the metal layer.

This approach avoids forming a metal thin film on the photosensitive film pattern when the seed layer is formed. As a result, waste of metal material can be prevented, which, in turn, significantly reduces manufacturing costs.

In addition, metal wiring can be formed to various thicknesses without causing a step height, and low-resistance metal wiring can be formed within the trench in a stable manner. Furthermore, since metal wiring is formed only within the trench, a width of the metal wiring can be adjusted precisely.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A method of forming metal wiring, the method comprising:
forming a photosensitive film pattern on a substrate;
forming a trench by etching the substrate using the photosensitive film pattern as a mask;
forming a seed layer by coating a fluid material, which contains metal, on the trench; and
forming a metal layer on the seed layer.

2. The method of claim 1, wherein at least part of the photosensitive film pattern is hydrophobicized.

3. The method of claim 2, wherein a surface of the photosensitive film pattern is hydrophobicized.

4. The method of claim 3, wherein the forming a photosensitive film pattern further comprises hydrophobicizing the photosensitive film pattern, the hydrophobicizing further comprising a fluorine-plasma treatment.

5. The method of claim 3, wherein the forming a photosensitive film pattern further comprises hydrophobicizing hydrophobicizing the photosensitive film pattern, the hydrophobicizing further comprising using octadecyl trichloro silane (OTS).

6. The method of claim 2, wherein the photosensitive film pattern comprises octadecyl trichloro silane.

7. The method of claim 2, wherein the fluid material comprises metal ink.

8. The method of claim 7, further comprising performing heat treatment after coating the metal ink.

9. The method of claim 1, wherein the fluid material comprises metal aerosol.

10. The method of claim 9, wherein the metal aerosol is fabricated by aerosolizing a metal material with an ultrasonic converter or a pneumatic sprayer.

11. The method of claim 10, wherein the metal aerosol is sprayed while at least any one of the substrate and an injection pipe is moved.

12. The method of claim 11, further comprising performing heat treatment after coating the metal aerosol.

13. The method of claim 1, wherein the metal layer is formed using electroplating, metal ink or metal aerosol.

14. A method of forming metal wiring, the method comprising:
forming an insulating film pattern on a substrate;
forming a seed layer by coating a fluid material, which contains metal, on a space between portions of the insulating film pattern; and
forming a metal layer on the seed layer.

15. The method of claim 14, wherein the forming an insulating film pattern further comprises hydrophobicizing at least part of the insulating film pattern before the seed layer is formed.

16. The method of claim 15, wherein the hydrophobicizing further comprises surface treatment using fluorine plasma or octadecyl trichloro silane.

17. The method of claim 15, wherein the fluid material comprises metal ink.

18. The method of claim 17, further comprising performing heat treatment after coating the metal ink.

19. The method of claim 15, wherein the fluid material comprises metal aerosol.

20. The method of claim 19, further comprising performing heat treatment after coating the metal aerosol.

21. The method of claim 14, wherein the metal layer is formed by at least one of electroplating, depositing a metal ink, and spraying a metal aerosol.

22. A metal wiring comprising:
a trench formed in a substrate;
a seed layer formed in the trench and comprising micropores; and
a metal layer formed on the seed layer in the trench.

23. The metal wiring of claim 22, wherein a surface level of the metal layer is equal to or lower than that of the substrate.

24. A metal wiring comprising:
an insulating film pattern formed on a substrate and comprising a predetermined space between portions thereof;
a seed layer formed in the predetermined space and comprising micropores; and
a metal layer formed on the seed layer in the predetermined space.

25. The metal wiring of claim 24, wherein a surface level of the metal layer is equal to or lower than that of the substrate.

26. A liquid crystal display (LCD) comprising:
a trench formed in a substrate;
a first seed layer formed in the trench and comprising first micropores;
a gate line formed on the first seed layer in the trench; and
a gate insulating film formed on the substrate and the gate line.

27. The LCD of claim 26, further comprising:
an insulating film pattern formed on the gate insulating film and comprising a predetermined space between portions thereof;
a second seed layer formed in the predetermined space and comprising second micropores; and
a data line formed on the second seed layer in the predetermined space,
wherein the predetermined space crosses the gate line.
